(19) United States
(12) Patent Application Publication
(10) Pub. No.: US 2024/0222402 A1
(43) Pub. Date: Jul. 4, 2024

(54) IMAGE SENSING DEVICE

(71) Applicant: SK hynix Inc., Icheon-si (KR)

(72) Inventor: Ho Ryeong LEE, Icheon-si (KR)

(21) Appl. No.: 18/358,860

(22) Filed: Jul. 25, 2023

(30) Foreign Application Priority Data
Dec. 28, 2022 (KR) 10-2022-0187171

(51) Int. Cl. H01L 27/146

(52) U.S. Cl. CPC H01L 27/14621; H01L 27/14645; H04N 25/78

(57) ABSTRACT

An image sensing device includes a plurality of first pixel blocks, each including a plurality of first imaging pixels configured to share one first color filter; a plurality of second pixel blocks, each including a plurality of second imaging pixels configured to share one second color filter having a second color filter; a plurality of third pixel blocks, each including a plurality of third imaging pixels configured to share one third color filter; an upper grid structure disposed in one or more boundary regions between the first to third pixel blocks within a region disposed in the first to third color filters; and a lower grid structure disposed between a substrate layer and each of the first to third color filters, at least a portion of to the lower grid structure vertically overlapping a boundary region of corresponding imaging pixels in each of the first to third pixel blocks.

### PRIORITY CLAIM AND CROSS-REFERENCE TO RELATED APPLICATION

This patent document claims the priority and benefits of Korean patent application No. 10-2022-0187171, filed on Dec. 28, 2022, which is incorporated by reference in its entirety as part of the disclosure of this patent document.

### TECHNICAL FIELD

The technology and implementations disclosed in this patent document generally relate to an image sensing device.

### BACKGROUND

An image sensor is used in electronic devices to convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, robots, etc.

As resolution of image sensors increases and pixel size decreases, there will be more fabrication issues caused by the decrease in pixel size.

### SUMMARY

Various embodiments of the disclosed technology relate to technology for increasing the size of a contact area between color filters by improving a color filter isolation structure.

In an embodiment of the disclosed technology, an image sensing device may include: a plurality of first pixel blocks, each first pixel block including a plurality of first imaging pixels arranged adjacent to each other and configured to share one first color filter having a first color to generate an image signal corresponding to the first color; a plurality of second pixel blocks, each second pixel block including a plurality of second imaging pixels arranged adjacent to each other and configured to share one second color filter having a second color to generate an image signal corresponding to the second color; a plurality of third pixel blocks, each third pixel block including a plurality of third imaging pixels arranged adjacent to each other and configured to share one third color filter having a third color to generate an image signal corresponding to the third color; an upper grid structure disposed in one or more boundary regions between the first, second, and third pixel blocks within a region disposed in the first, second, and third color filters; and a lower grid structure disposed between a substrate layer and each of the first, second, and third color filters, at least a portion of the lower grid structure vertically overlapping a boundary region of corresponding imaging pixels in each of the first, second, and third pixel blocks.

In another embodiment of the disclosed technology, an image sensing device may include a substrate layer configured to include a plurality of photoelectric conversion elements and a pixel isolation layer structured to isolate the photoelectric conversion elements from each other; a plurality of color filters disposed over the substrate layer, wherein each of the color filters is arranged to cover two or more of the plurality of photoelectric conversion elements; an upper grid structure disposed between the color filters to overlap the pixel isolation layer; and a lower grid structure disposed between the substrate layer and the color filters to overlap the pixel isolation layer.

In another embodiment of the disclosed technology, an image sensing device may include: a plurality of first pixel blocks, each of which includes a plurality of first imaging pixels that shares one first color filter having a first color to generate an image signal corresponding to the first color while being adjacent to each other; a plurality of second pixel blocks, each of which includes a plurality of second imaging pixels that shares one second color filter having a second color to generate an image signal corresponding to the second color while being adjacent to each other; a plurality of third pixel blocks, each of which includes a plurality of third imaging pixels that shares one third color filter having a third color to generate an image signal corresponding to the third color while being adjacent to each other; an upper grid structure disposed in a boundary region between the first to third pixel blocks within a region disposed in the first to third color filters; and a lower grid structure disposed between a substrate layer and each of the first to third color filters, at least a portion of which is formed to vertically overlap a boundary region of corresponding imaging pixels in each of the first to third pixel blocks.

In another embodiment of the disclosed technology, an image sensing device may include a substrate layer configured to include a plurality of photoelectric conversion elements and a pixel isolation layer for isolating the photoelectric conversion elements from each other; a plurality of color filters disposed over the substrate layer in a manner that one color filter is arranged to cover the plurality of photoelectric conversion elements; an upper grid structure disposed between the color filters to overlap the pixel isolation layer; and a lower grid structure disposed between the substrate layer and the color filters to overlap the pixel isolation layer.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

FIG. 1 is a block diagram illustrating an example of an image sensing device based on some implementations of the disclosed technology.

FIG. 2 is a schematic diagram illustrating an example of a pixel array in the image sensing device shown in FIG. 1 based on some implementations of the disclosed technology.

FIG. 3 is a cross-sectional view illustrating an example of the pixel array taken along the line A-A′ shown in FIG. 2 based on some implementations of the disclosed technology.

FIG. 4 is a cross-sectional view illustrating an example of the pixel array taken along the line B-B′ shown in FIG. 2 based on some implementations of the disclosed technology.

FIG. 5 is a schematic diagram illustrating an example of the pixel array of FIG. 1 based on some implementations of the disclosed technology.

FIG. 6 is a schematic diagram illustrating an example of the pixel array of FIG. 1 based on some implementations of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of a method for increasing the size of a contact area between color filters by improving a color filter isolation structure. The disclosed technology provides various implementations of the image sensing device that can increase the size of a contact area between the color filters.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

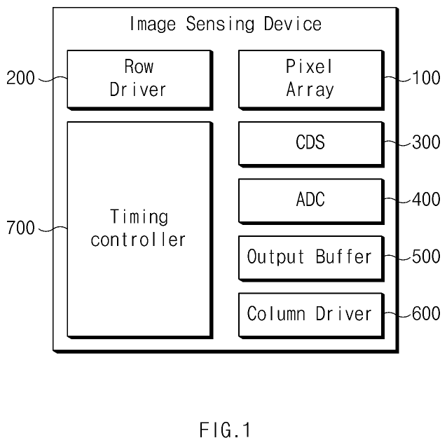

FIG. 1 is a block diagram illustrating an image sensing device based on some implementations of the disclosed technology.

Referring to FIG. 1, the image sensing device may include a pixel array 100, a row driver 200, a correlated double sampler (CDS) 300, an analog-to-digital converter (ADC) 400, an output buffer 500, a column driver 600 and a timing controller 700. The components of the image sensing device illustrated in FIG. 1 are discussed by way of example only, and this patent document encompasses numerous other changes, substitutions, variations, alterations, and modifications.

The pixel array 100 may include a plurality of imaging pixels arranged in rows and columns. Each of the imaging pixels may generate an electrical signal (pixel signal) in response to incident light through photoelectric conversion of incident light received from the outside. The pixel array 100 may include a plurality of pixel blocks, each of which is configured in a manner that a plurality of imaging pixels having color filters of the same color is arranged adjacent to each other. For example, each pixel block may have the colors filters having the same color, and may include a plurality of imaging pixels arranged in an (N×N) array (where N is a natural number of 2 or greater). The pixel blocks may be arranged in a Bayer pattern. The pixel array 100 may include a grid structure of a double-layer isolation structure to prevent crosstalk between adjacent pixels on a substrate.

The row driver 200 may activate the pixel array 100 to perform certain operations on the imaging pixels in the corresponding row based on control signals provided by controller circuitry such as the timing controller 700. In some implementations, the row driver 200 may select one or more imaging pixels arranged in one or more rows of the pixel array 100. The row driver 200 may generate a row selection signal to select one or more rows from among the plurality of rows. The pixel signals generated by the imaging pixels arranged in the selected row may be output to the correlated double sampler (CDS) 300.

The correlated double sampler (CDS) 300 may remove undesired offset values of the imaging pixels using correlated double sampling. In some implementations, the CDS 300 may transfer a reference signal and a pixel signal of each of the columns as a correlate double sampling (CDS) signal to the ADC 400.

The ADC 400 is used to convert analog CDS signals received from the CDS 300 into digital signals. The analog-to-digital converter (ADC) 400 may count a level transition time of the comparison signal in response to a ramp signal received from the timing controller 700, and may output a count value indicating the counted level transition time to the output buffer 500.

The output buffer 500 may temporarily store column-based image data provided from the ADC 400 based on control signals of the timing controller 700.

The column driver 600 may select a column of the output buffer 500 upon receiving a control signal from the timing controller 700, and sequentially output the image data, which are temporarily stored in the selected column of the output buffer 500.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column.

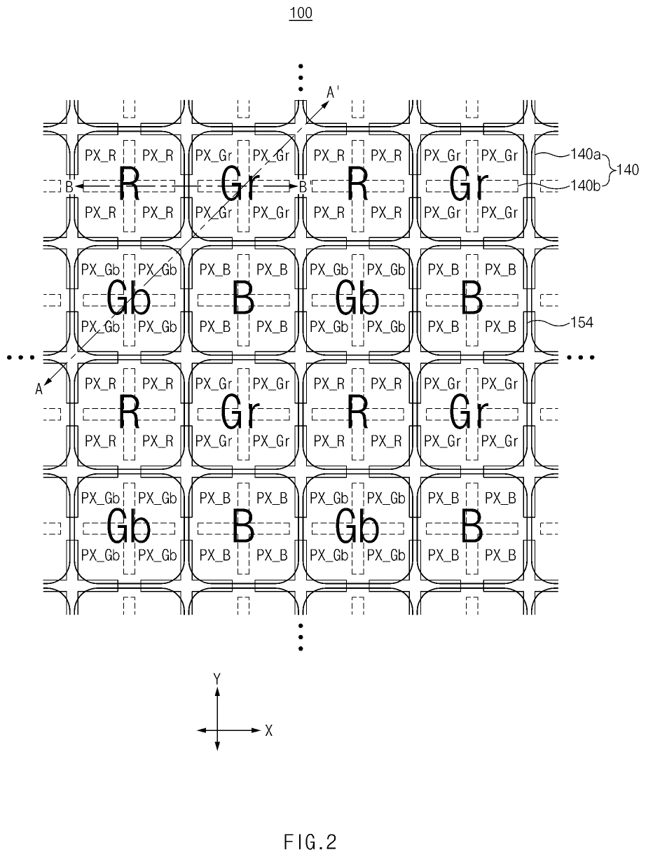

FIG. 2 is a schematic diagram illustrating an example of the pixel array 100 shown in FIG. 1 based on some implementations of the disclosed technology.

Referring to FIG. 2, the pixel array 100 may include a plurality of imaging pixels consecutively arranged in row and column directions.

Each of the plurality of imaging pixels may be a unit pixel that generates an image signal (pixel signal) corresponding to a target object to be captured. In some implementations, each of the plurality of imaging pixels may independently generates an image signal corresponding to a target object to be captured.

The plurality of imaging pixels may include red pixels (PX_R) formed to generate image signals corresponding to red light (light at a wavelength corresponding to red color), green pixels (PX_Gr, PX_Gb) formed to generate image signals corresponding to green light (light at a wavelength corresponding to green color), and blue pixels (PX_B) formed to generate image signals corresponding to blue light (light at a wavelength corresponding to blue color). The red pixel (PX_R) may include a red color filter (R). The green pixel (PX_Gr) may include a green color filter (Gr), and the green pixel (PX_Gb) may include a green color filter (Gb). The blue pixel (PX_B) may include a blue color filter (B).

The plurality of imaging pixels may be arranged such that imaging pixels generating image signals corresponding to light of the same color are arranged adjacent to each other in an (N×N) array (where N is a natural number equal to or greater than 2). For example, the pixel array 100 may include red pixel blocks, each of which includes four red pixels (PX_R) arranged adjacent to each other in a (2×2) array, green pixel blocks, each of which includes four green pixels (PX_Gr) arranged adjacent to each other in a (2×2) array, other green pixel blocks, each of which includes four green pixels (PX_Gb) arranged adjacent to each other in a (2×2) array, and blue pixel blocks, each of which includes four blue pixels (PX_B) arranged adjacent to each other in a (2×2) array. The red pixel blocks, the green pixel blocks, and the blue pixel blocks may be arranged in a Bayer pattern. In some implementations, each pixel block may include a set of imaging pixels.

In some implementations, each of the color filters (R, G, B) may correspond to a pixel block. For example, each color filter (R, Gr, Gb, B) may be disposed over a set of imaging pixels (PX_R, PX_Gr, PX_Gb, PX_B). For example, a red color filter R is disposed over a plurality of “red” imaging pixels (e.g., 4 PX_R as shown in FIG. 2), which constitute a “red” pixel block. As such, in this example, four imaging pixels PX_R share one large red color filter.

The pixel array 100 may include one or more grid structures 140, each of which includes a double layer isolation structure disposed between color filters of adjacent imaging pixels on the substrate layer. Each of the one or more grid structures 140 may include an upper grid structure 140a and a lower grid structure 140b.

The upper grid structure 140a may be disposed between color filters (R, Gr, Gb, B) of different colors. For example, the upper grid structure 140a may be located in a region (e.g., boundary region) between adjacent pixel blocks in the row or column direction at the same level as a color filter layer.

When viewed in a plane, the upper grid structure 140a may include a cross-shaped structure that includes a region extending in the X-axis direction (or in the row direction) and a region extending in the Y-axis direction (or in the column direction) that cross each other in a boundary region of four pixel blocks adjacent to each other in a (2×2) array. For example, a region where each pixel block is formed may be surrounded by four cross-shaped structures.

The lower grid structure 140b may be disposed below a corresponding color filter (R, Gr, Gb, B), and may be disposed to overlap a boundary region of adjacent imaging pixels within each pixel block. For example, the lower grid structure 140b may be disposed between the substrate layer and the color filters (R, Gr, Gb, B) to overlap a boundary region of the imaging pixels within each pixel block.

When viewed in a plane, the lower grid structure 140b may include a cross-shaped structure that includes a region extending in the X-axis direction (or in the row direction) and a region extending in the Y-axis direction (or in the column direction) that cross each other.

In this case, the region extending in the X-axis direction within the lower grid structure 140b may overlap an X-directional central line of the corresponding color filter, and the region extending in the Y-axis direction within the lower grid structure 140b may overlap a Y-directional central line of the corresponding color filter. In some implementations, the cross-shaped upper grid structure 140a and the cross-shaped lower grid structure 140b do not vertically overlap each other.

In some implementations, a grid structure may be disposed between the color filters of adjacent imaging pixels within the color filter layer to reduce or prevent optical crosstalk or interference between adjacent color filters. However, as the number of pixels of the image sensing device increases, a gap between the grid structures decreases, making it difficult to form the color filters within a corresponding region (e.g., a region defined by the grid structure). In addition, the size of a bottom surface of the color filters corresponding to each imaging pixel decreases, and thus the color filters may be subject to separation during a subsequent thermal annealing process.

In some implementations, a plurality of imaging pixels generating image signals corresponding to the same color may be arranged adjacent to each other in units of an (N×N) block (where N is a natural number equal to or greater than 2), and imaging pixels of each block (pixel block) are arranged to share only one color filter. In addition, an upper grid structure may be formed only in a boundary region between the pixel blocks. For the imaging pixels (PX_R, PX_Gr, PX_Gb, PX_B) for each pixel block, a lower grid structure may be formed below the corresponding color filters (R, Gr, Gb, B) to overlap a boundary region between the corresponding imaging pixels.

Although FIG. 2 shows the upper grid structure 140a and the lower grid structure 140b as being formed in a cross shape, the disclosed technology is not limited thereto.

The microlens 154 may be formed for each pixel block so that one microlens 154 is formed to cover a plurality of imaging pixels (e.g., four imaging pixels in FIG. 2) included in each pixel block.

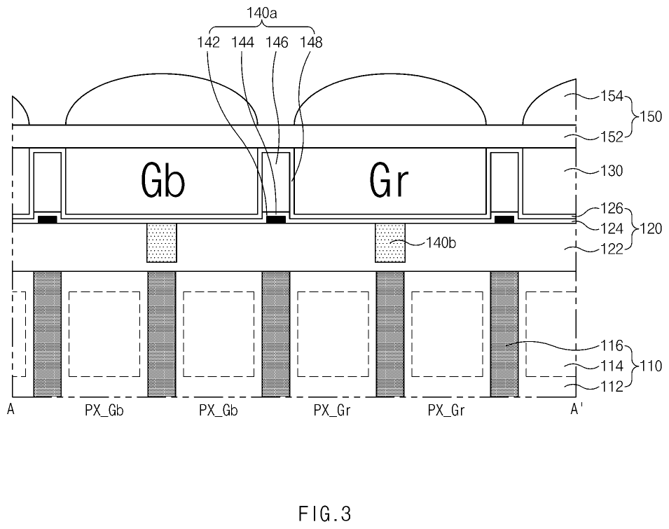

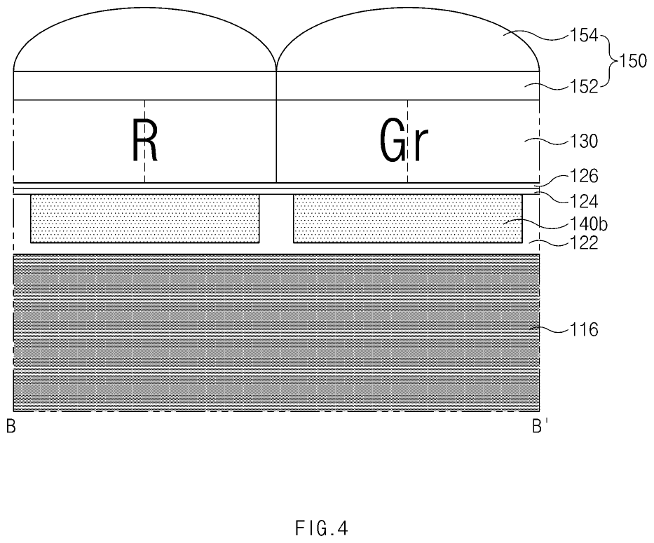

FIG. 3 is a cross-sectional view illustrating an example of the pixel array 100 taken along the line A-A′ shown in FIG. 2 based on some implementations of the disclosed technology. FIG. 4 is a cross-sectional view illustrating an example of the pixel array 100 taken along the line B-B′ shown in FIG. 2 based on some implementations of the disclosed technology.

Referring to FIGS. 3 and 4, the pixel array 100 may include a substrate layer 110, an anti-reflection layer 120, a color filter layer 130, a grid structure 140, and a lens layer 150.

The substrate layer 110 may include a substrate 112, a plurality of photoelectric conversion regions 114, and a plurality of pixel isolation layers 116. The substrate layer 110 may include a first surface and a second surface facing away from or opposite to the first surface. In this case, the first surface may refer to a light receiving surface upon which light is incident from the outside, and the color filter layer 130 and the lens layer 150 may be formed over the first surface. Pixel transistors (not shown) that can be used to read out photocharges generated by the photoelectric conversion region 114 of the corresponding imaging pixel may be formed in each imaging pixel region of the second surface.

The substrate 112 may include a semiconductor substrate including a monocrystalline silicon material. The substrate 112 may include P-type impurities.

The photoelectric conversion regions 114 may be formed in the semiconductor substrate 112 and each photoelectric conversion region 114 can correspond to each imaging pixel. The photoelectric conversion regions 114 may perform photoelectric conversion of incident light (e.g., visible light) filtered by the color filter layer 130 to generate photocharge corresponding to images in the incident light. Each of the photoelectric conversion regions 114 may include N-type impurities.

Each of the pixel isolation layer 116 may be formed between photoelectric conversion regions 114 of the adjacent imaging pixels within the substrate 112 to isolate the photoelectric conversion regions 114 from each other. The pixel isolation layer 116 may include a trench structure such as a Back Deep Trench Isolation (BDTI) structure or a Front Deep Trench Isolation (FDTI) structure. Alternatively, the pixel isolation layer 116 may include a junction isolation structure formed by implanting high-density impurities (e.g., P-type impurities) into the substrate 112.

The anti-reflection layer 120 may be disposed over the first surface of the substrate layer 110, and may prevent reflection of light so that light incident upon the first surface of the substrate layer 110 can effectively reach the photoelectric conversion regions 114. For example, the anti-reflection layer 120 may compensate for a difference in refractive index between the substrate layer 110 and the color filter layer 130, and may thus enable light having penetrated the color filter layer 130 to be effectively incident upon the substrate layer 110. The anti-reflection layer 120 may operate as a planarization layer to flatten the surface topography of the substrate layer 110.

The anti-reflection layer 120 may include a first anti-reflection layer 122, a second anti-reflection layer 124, and a third anti-reflection layer 126. The lower grid structure 140b may be formed in the first anti-reflection layer 122. The second anti-reflection layer 124 and the third anti-reflection layer 126 may be disposed between the first anti-reflection layer 122 and the color filters (R, G, B). In some implementations, the second anti-reflection layer 124 and the third anti-reflection layer 126 may be the same layer as the capping layers 144 and 148 of the upper grid structure 140a. For example, the second anti-reflection layer 124 and the third anti-reflection layer 126 may be formed so that the capping layers 144 and 148 can extend to a region between the first anti-reflection layer 122 and the color filters (R, G, B). That is, in some implementations, although reference numerals of the second anti-reflection layer 124 and the third anti-reflection layer 126 are different from those of the capping layers 144 and 148 for convenience of description, it should be noted that the second anti-reflection layer 124, the capping layer 144, the third anti-reflection layer 126, and the capping layer 148 can be simultaneously formed through the same process as necessary.

Each of the anti-reflection layers (122, 124, 126) may include a silicon oxide layer, a silicon nitride layer, a silicon oxynitride layer, or a high-permittivity (high-K) layer (e.g., a hafnium oxide layer or an aluminum oxide layer).

The color filter layer 130 may be disposed over the anti-reflection layer 120, and may include a plurality of color filters (R, G, B) that filters visible light from among incident light received through the lens layer 150 and transmit the filtered light to the corresponding photoelectric conversion regions 114. For example, the color filter layer 130 may include a plurality of red color filters (R), a plurality of green color filters (Gr, Gb), and a plurality of blue color filters (B). Each red color filter (R) may transmit red visible light. Each green color filter (G) may transmit green visible light. Each blue color filter (B) may transmit blue visible light.

In some implementations, the color filters (R, Gr, Gb, B) may be formed in a region defined by the upper grid structure 140a. For example, each of the color filters (R, Gr, Gb, B) correspond to a pixel block. As such, since each of the color filters (R, Gr, Gb, B) is disposed over a set of imaging pixels (PX_R, PX_Gr, PX_Gb, PX_B) and have a larger size than each imaging pixel, a contact area between the anti-reflection layer 120 and the color filters (R, Gr, Gb, B) can increase. As a result, the structural stability of the color filters (R, Gr, Gb, B) may be improved.

The grid structure 140 may include the upper grid structure 140a disposed between the color filters (R, Gr, Gb, B) over the anti-reflection layer 120, and the lower grid structure 140b disposed to overlap a boundary region between the imaging pixels (PX_R, PX_Gr, PX_Gb, PX_B) while overlapping the color filters (R, Gr, Gb, B) within the first anti-reflection layer 122. The upper grid structure 140a and the lower grid structure 140b may be formed to overlap the pixel isolation layer 116.

The upper grid structure 140a may be disposed between adjacent pixel blocks to reduce or prevent optical crosstalk between the color filters (R, Gr, Gb, B) having different colors. The upper grid structure 140a may include an air layer, a metal layer, or a hybrid structure in which the air layer and the metal layer are stacked. For example, the upper grid structure 140a may include a metal layer 142, a first capping layer 144, an air layer 146, and a second capping layer 148.

The metal layer 142 may include a metal material (e.g., tungsten) having a high light absorption rate, and may be formed by stacking different materials based on some embodiments of the disclosed technology. For example, the metal layer 142 may further include a barrier metal layer (not shown) disposed below the tungsten layer. The air layer 146 may be formed over the first capping layer 144 to overlap the metal layer 142. The air layer 146 may be a region that includes or is filled with air.

The first capping layer 144 may include a nitride layer, and may be formed to extend below the color filters (R, Gr, Gb, B) while covering the metal layer 142. The first capping layer 144 may prevent expansion of the metal layers 142 during a thermal annealing process. A region formed under the color filter layer 130 in the first capping layer 144 may be used as the second anti-reflection layer 124. The second capping layer 148 may be a material layer formed at the outermost portion of the upper grid structure 140a, and may define a region in which the air layer 146 is formed. The second capping layer 148 may include an oxide layer, and may be formed to extend below the color filter layer 130 while covering the air layer 146 and the metal layer 142. The oxide layer may include an ultra-low temperature oxide (ULTO) layer such as a silicon oxide (SiO2) layer. A region formed under the color filter layer 130 in the second capping layer 148 may be used as the third anti-reflection layer 126.

Although FIG. 3 shows the upper grid structure 140a as including the metal layer 142, the first capping layer 144, the air layer 146, and the second capping layer 148, the disclosed technology is not limited thereto.

The lower grid structure 140b may be disposed for each pixel block within the first anti-reflection layer 122. The lower grid structure 140b may be disposed to overlap the boundary regions of the imaging pixels (PX_R, PX_Gr, PX_Gb, PX_B) within each pixel block, thereby reducing or preventing crosstalk between adjacent imaging pixels sharing a same color filter. The lower grid structure 140b may include an insulating material or metal material capable of preventing transmission of incident light. Alternatively, the lower grid structure 140b may also include an air layer.

One or more lower grid structures 140b may be formed to overlap the pixel isolation layer 116. The lower grid structures 140b formed in each pixel block may be formed to be physically separated from each other.

In some implementations, the upper grid structure 140a may be formed in a boundary region between pixel blocks within the same layer as the color filters (R, Gr, Gb, B) to reduce or prevent crosstalk between the color filters (R, Gr, Gb, B) having different colors. The lower grid structure 140b may be formed in a boundary region between the corresponding imaging pixels for each pixel block under the color filters (R, Gr, Gb, B), thereby reducing or preventing crosstalk between the imaging pixels for incident light having penetrated the color filters having the same color.

The lens layer 150 may include an overcoating layer 152 and a plurality of microlenses 154. The overcoating layer 152 may operate as a planarization layer to flatten the surface topography of the color filter layer 130. The microlenses 154 may be formed over the overcoating layer 152. Each of the microlenses 154 may be formed in a convex lens shape, and may be formed for each unit pixel. The microlenses 154 may converge incident light, and may transmit the converged light to the corresponding photoelectric conversion regions 114. The overcoating layer 152 and the microlenses 154 may be formed of the same materials.

In FIGS. 3 and 4, the upper grid structure 140a and the lower grid structure 140b may be disposed to overlap the pixel isolation layers 116 as a whole. However, in order to reduce or minimize negative effects from shading variation, the upper grid structure 140a and the lower grid structure 140b may be shifted by a predetermined distance corresponding to a chief ray angle (CRA) according to where the corresponding imaging pixel is placed in the pixel array 100.

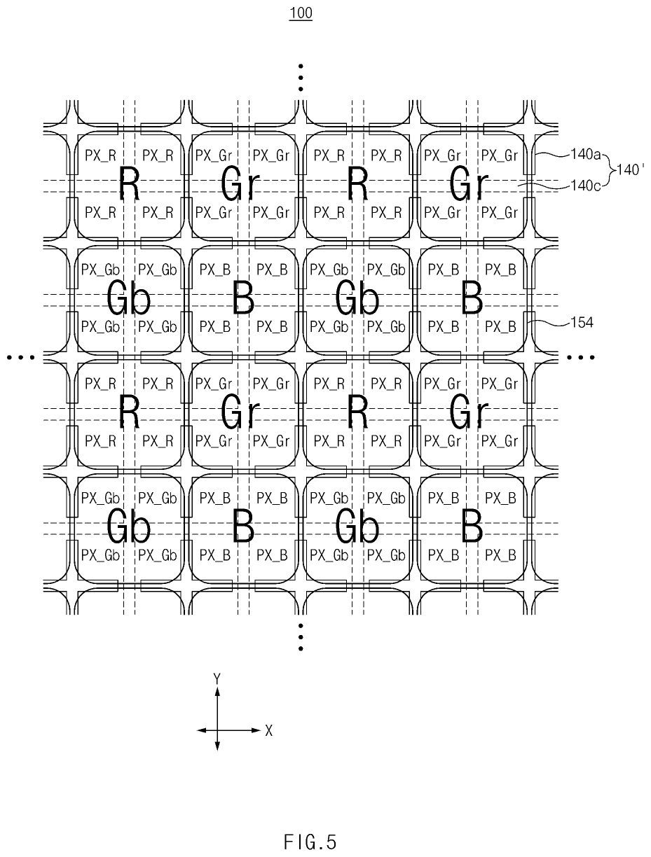

FIG. 5 is a schematic diagram illustrating an example of the pixel array 100 of FIG. 1 based on some implementations of the disclosed technology.

Referring to FIG. 5, the pixel array 100 may include a grid structure 140′ having a double layer isolation structure that is disposed between color filters of adjacent imaging pixels on the substrate layer. The grid structure 140′ may include an upper grid structure 140a and a lower grid structure 140c.

In some implementations, different from the above-described grid structure 140 shown in FIG. 2, the grid structure 140′ of FIG. 5 includes the lower grid structure 140c having a structure different from the lower grid structure 140b, whereas the upper grid structure 140a of FIG. 5 has a structure identical to the upper grid structure 140a included in the above-described grid structure 140.

In some implementations, as shown in FIG. 2, the lower grid structure 140b may be formed such that cross-shaped structures formed for each pixel block can be physically separated from each other.

In some implementations, as shown in FIG. 5, the lower grid structure 140c may be configured in a manner that the cross-shaped structures formed for each pixel block further extend in the X-axis and Y-axis directions, so that the cross-shaped structures present in adjacent pixel blocks may be connected to each other. For example, the lower grid structure 140c may include a plurality of line-shaped regions spaced apart from each other by a predetermined distance therebetween while extending to cross a plurality of pixel blocks in the X-axis direction, and a plurality of other line-shaped regions spaced apart from each other by a predetermined distance therebetween while extending to cross a plurality of pixel blocks in the Y-axis direction, such that the plurality of line-shaped regions may be disposed to cross the plurality of other line-shaped regions.

In this case, imaging pixels disposed in each region defined by the lower grid structure 140c may generate image signals corresponding to different colors, and the corresponding imaging pixels may be arranged in a Bayer pattern.

In some implementations, the remaining structures in FIG. 5 other than the lower grid structure 140c formed to further extend in the X and Y directions may be formed in the same manner as the structures shown in FIG. 2.

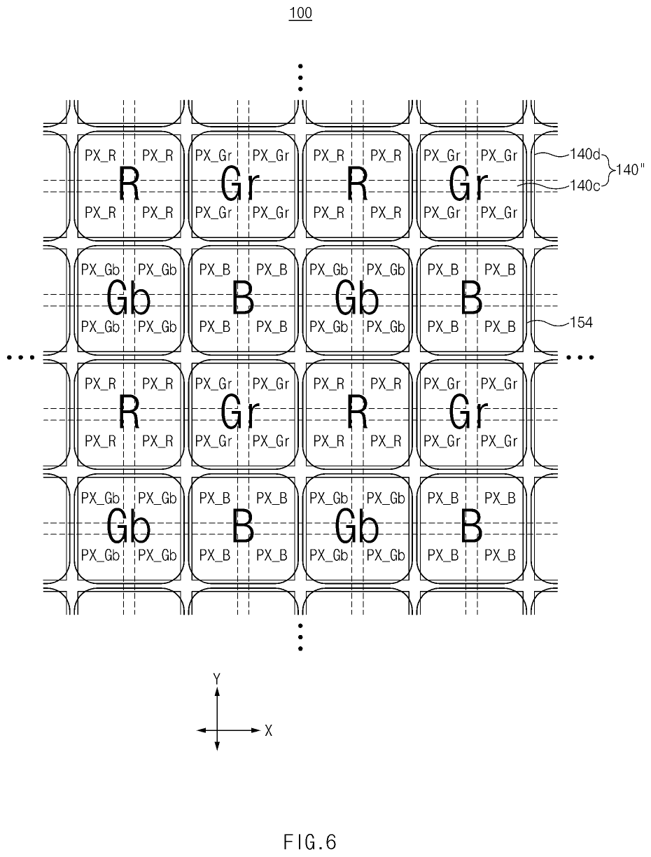

FIG. 6 is a schematic diagram illustrating an example of the pixel array 100 of FIG. 1 based on some implementations of the disclosed technology.

Referring to FIG. 6, the pixel array 100 may include a grid structure 140″ having a double layer isolation structure that is disposed between color filters of adjacent imaging pixels on the substrate layer. The grid structure 140″ may include an upper grid structure 140d and a lower grid structure 140c.

In some implementations, different from the grid structure 140 shown in FIG. 2, the grid structure 140″ of FIG. 6 includes the upper grid structure 140d and the lower grid structure 140c having different structures from the upper grid structure 140a and the lower grid structure 140b shown in FIG. 2. In addition, different from the grid structure 140′ of FIG. 5, the upper grid structure 140d of FIG. 6 has a different structure from the upper grid structure 140a, whereas the lower grid structure 140c of FIG. 6 is the same as the lower grid structure 140c of FIG. 5.

In some implementations, as shown in FIGS. 2 and 5, each of the upper grid structures 140a may be formed in a cross-shaped structure in which a region extending in the X-axis direction in a boundary region between four pixel blocks adjacent to each other in a (2×2) array is formed to cross a region extending in the Y-axis direction, and the cross-shaped structures formed between the adjacent pixel blocks in the pixel array 100 can be physically isolated from each other.

In some implementations, as shown in FIG. 6, the upper grid structure 140d may be configured in a manner that the cross-shaped structures thereof can further extend in the X and Y directions and be connected to each other in the same manner as in the lower grid structure 140c.

In some implementations, the remaining structures in FIG. 6 other than the upper grid structure 140d and the lower grid structure 140c may be formed in the same manner as the structures shown in FIG. 2.

In some implementations, the lower grid structure can also be implemented as cross-shaped structures as in the embodiment of FIG. 2.

In some implementations, each pixel block includes four imaging pixels arranged in a (2×2) pixel array. In some implementations, each pixel block may include a plurality of imaging pixels arranged in K×K pixel array (K is a natural number equal to or greater than 3), such as 3×3, 4×4. In some implementations, each pixel block may include a plurality of imaging pixels arranged in L×M pixel array (L and M are natural numbers). In some implementations, each of the color filters may correspond to each pixel block, so that the plurality of imaging pixels included in the corresponding pixel block may share only one color filter. In addition, the upper grid structure may be disposed in a boundary region between the pixel blocks within the same layer as the color filters, and the lower grid structure may be disposed in a boundary region between the imaging pixels within each pixel block under the color filters.

As is apparent from the above description, the image sensing device based on some implementations of the disclosed technology can increase the size of a contact area between the color filters.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a plurality of first pixel blocks, each first pixel block including a plurality of first imaging pixels arranged adjacent to each other and configured to share one first color filter having a first color to generate an image signal corresponding to the first color;
a plurality of second pixel blocks, each second pixel block including a plurality of second imaging pixels arranged adjacent to each other and configured to share one second color filter having a second color to generate an image signal corresponding to the second color;
a plurality of third pixel blocks, each third pixel block including a plurality of third imaging pixels arranged adjacent to each other and configured to share one third color filter having a third color to generate an image signal corresponding to the third color;
an upper grid structure disposed in one or more boundary regions between the first, second, and third pixel blocks within a region disposed in the first, second, and third color filters; and
a lower grid structure disposed between a substrate layer and each of the first, second, and third color filters, at least a portion of the lower grid structure vertically overlapping a boundary region of corresponding imaging pixels in each of the first, second, and third pixel blocks.

2. The image sensing device according to claim 1, wherein each of the first, second, and third pixel blocks includes a plurality of imaging pixels that shares a color filter and is arranged adjacent to each other in an N×N array, wherein where N is a natural number equal to or greater than 2.

3. The image sensing device according to claim 1, wherein the upper grid structure includes a plurality of cross-shaped structures, wherein each cross-shaped structure includes a region that extends in a first direction and is disposed to cross a region extending in a second direction perpendicular to the first direction.

4. The image sensing device according to claim 3, wherein the upper grid structure includes cross-shaped structures that are arranged adjacent to each other and physically isolated from each other.

5. The image sensing device according to claim 3, wherein the lower grid structure includes a plurality of cross-shaped structures, wherein each of the plurality of cross-shaped structures includes a region extending in the first direction and a region extending in the second direction that are disposed to cross each other within each of the first, second, and third pixel blocks.

6. The image sensing device according to claim 5, wherein the upper grid structure and the lower grid structure do not overlap each other.

7. The image sensing device according to claim 3, wherein the lower grid structure includes:
a plurality of first line-shaped regions spaced apart from each other by a predetermined distance and extending to cross a plurality of pixel blocks in the first direction; and
a plurality of second line-shaped regions spaced apart from each other by a predetermined distance and extending to cross a plurality of pixel blocks in the second direction,
wherein the plurality of first line-shaped regions and the plurality of second line-shaped regions are formed to cross each other.

8. The image sensing device according to claim 7, wherein the first to third imaging pixels are arranged in a Bayer pattern within regions defined by the lower grid structure.

9. The image sensing device according to claim 1, wherein the upper grid structure includes:
a plurality of first line-shaped regions spaced apart from each other by a predetermined distance and extending in a first direction; and
a plurality of second line-shaped regions spaced apart from each other by a predetermined distance and extending in a second direction perpendicular to the first direction,
wherein the plurality of first line-shaped regions and the plurality of second line-shaped regions are formed to cross each other.

10. The image sensing device according to claim 9, wherein the lower grid structure includes:
a plurality of third line-shaped regions spaced apart from each other by a predetermined distance and extending to cross a plurality of pixel blocks in the first direction; and
a plurality of fourth line-shaped regions spaced apart from each other by a predetermined distance and extending to cross a plurality of pixel blocks in the second direction,
wherein the plurality of third line-shaped regions and the plurality of fourth line-shaped regions are formed to cross each other.

11. The image sensing device according to claim 9, wherein the lower grid structure includes a plurality of cross-shaped structures, wherein each of the plurality of cross-shaped structures includes a region extending in the first direction and a region extending in the second direction that are disposed to cross each other within each of the first, second, and third pixel blocks.

12. The image sensing device according to claim 1, wherein the upper grid structure includes:
a metal layer;
an air layer disposed over the metal layer; and
a capping layer formed to cover the metal layer and the air layer.

13. The image sensing device according to claim 12, wherein the capping layer is structured to extend below the first to third color filters.

14. The image sensing device according to claim 13, further comprising an anti-reflection layer disposed between the substrate layer and the capping layer,
wherein the lower grid structure is disposed in the anti-reflection layer.

15. An image sensing device comprising:
a substrate layer configured to include a plurality of photoelectric conversion elements and a pixel isolation layer structured to isolate the photoelectric conversion elements from each other;
a plurality of color filters disposed over the substrate layer, wherein each of the color filters is arranged to cover two or more of the plurality of photoelectric conversion elements;
an upper grid structure disposed between the color filters to overlap the pixel isolation layer; and
a lower grid structure disposed between the substrate layer and the color filters to overlap the pixel isolation layer.

16. The image sensing device according to claim 15, wherein each of the plurality of color filters is disposed to overlap the photoelectric conversion elements of a plurality of imaging pixels arranged adjacent to each other in an N×N array, wherein N is a natural number equal to or greater than 2.

17. The image sensing device according to claim 15, wherein the upper grid structure includes a plurality of cross-shaped structures, wherein each cross-shaped structure includes a region that extends in a first direction and is disposed to cross a region extending in a second direction perpendicular to the first direction.

18. The image sensing device according to claim 17, wherein the lower grid structure includes a plurality of cross-shaped structures disposed below a corresponding color filter for each of the color filters,
wherein each of the cross-shaped structure includes a region extending in the first direction and a region extending in the second direction that are disposed to cross each other.

19. The image sensing device according to claim 18, wherein the upper grid structure and the lower grid structure do not overlap each other.

20. The image sensing device according to claim 17, wherein the lower grid structure includes:
a plurality of first line-shaped regions spaced apart from each other by a predetermined distance and extending to cross a plurality of pixel blocks in the first direction; and
a plurality of second line-shaped regions spaced apart from each other by a predetermined distance and extending to cross a plurality of pixel blocks in the second direction,
wherein the plurality of first line-shaped regions and the plurality of second line-shaped regions are formed to cross each other.
